(19) United States
(12) Patent Application Publication
(10) Pub. No.: US 2009/0051044 A1
(43) Pub. Date: Feb. 26, 2009

(54) Wafer-level packaged structure and method for making the same

(76) Inventors: Chung-Er Huang, Taipei (TW); Yueh-Cheng Lee, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/987,147

(22) Filed: Nov. 28, 2007

(30) Foreign Application Priority Data
Aug. 22, 2007 (TW) 96131059

(51) Int. Cl. H01L 23/31; H01L 21/78

(52) U.S. Cl. 257/777; 438/113; 257/E23.116; 257/E21.599

(57) ABSTRACT

A wafer-level packaging method is shown below: providing an un-cut wafer having a front side and a back side. A plurality of cutting lines is formed on the front side of the wafer so as to define the positions of each chip module such as a wireless module. The next step is providing an extendible film attached onto the back side of the wafer. Next is dicing the wafer along the cutting line to separate each chip module and expending the extendible film so that a gap is formed between each chip module. At last, filling a packaging compound onto the front side and the lateral side of the chip module produces a packaged structure. As mentioned above, the structure is employed for protecting the external surface of the chip.

### BACKGROUND OF THE INVENTION

1. Field of the Invention

The present invention relates to a wafer-level packaged structure and in particular to a packaged structure covering the lateral side of the chip.

2. Description of Prior Art

Resulting from the development of semiconductor processes, semiconductor chips have become more and more powerful. Hence the number of pins on a chip has also increased because of the multi function integrated. Thus, the packaging technology to protect the chip has a direct impact on improving chip quality. Laptop computers, mobile phones and digital cameras are more and more light-weight and small-size in so that users can carry along the devices. Therefore, not only the performance and the transmission quality of chip modules but also their integration needs to be optimized.

For example, the requirement for memory capacity is increasing because multimedia applications are becoming more common. However, as the size of mobile phones is reduced there is less space for installing the memory. As mobile phones become small, the memory, for instance NOR flash, NAND flash, low power SRAM and Pseudo SRAM are packaged using multi-chip packaging technology.

The normal purpose of packaging is to isolate the chip from air and moisture. Some special effects have also been developed as for example dissipating heat from the modules. Excess heat arises due to the higher performance of chips, and it may cause damage to chip modules and systems.

However, the conventional packaged structure often has disadvantages as shown in FIG. 1. The portion 141 of chip module 14 is covered by covering material 16′, but the covering material does not cover the lateral surface of chip module 14. The chip module 14 is typically made of fragile material and will break due to crashing or colliding. In other words, the conventionally packaged structure is not capable of protecting chips.

Therefore, in view of this, the inventor proposes the present invention to overcome the above problems based on his expert experience and deliberate research.

### SUMMARY OF THE INVENTION

The primary object of the present invention is to provide a wafer-level packaged structure and a manufacturing method therefor. The wafer-level packaged structure is provided to cover the lateral surface of the chip so that the chip is protected from damage and has better mechanical properties.

The wafer-level packaged structure comprises: a chip module having a front side and a lateral side; a device portion disposed on the front side of the chip module; and a covering layer covering the device portion and the lateral side of the chip module.

In order to achieve the above structure, the present invention provides a method for manufacturing the wafer-level packaged structure. The method comprises (a) providing an uncut wafer having a plurality of chip modules thereon, wherein the uncut wafer has a front side and a back side connected to the front side, and the front side has a plurality of cutting lines thereon for defining positions of the chip modules; (b) attaching an extendible film on the back side of the uncut wafer; (c) cutting the uncut wafer along the cutting lines for separating the chip modules; (d) extending the extendible film and forming gaps between the chip modules; and (e) forming a covering layer for covering front sides and lateral sides of the chip modules.

Depending on the present invention, the extendible film is provided for moving the chip modules relatively to each other so that the lateral side of the chip module can be exposed. The covering material can be filled between the chip modules so as to protect the lateral sides of the chip module.

In order to better understand the characteristics and technical contents of the present invention, a detailed description thereof will be made with reference to the accompanying drawings. However, it should be understood that the drawings and the description are illustrative but not used to limit the scope of the present invention.

### BRIEF DESCRIPTION OF THE DRAWINGS

FIG. 1 is a schematic view of a packaged structure according to the prior art;

FIG. 2 is a flow chart showing the method for manufacturing the wafer-level packaged structure according to the present invention;

FIG. 3 is a top view showing the uncut wafer according to the present invention;

FIG. 4 is a top view showing the chip modules after the extending step according to the present invention;

FIG. 4A is a side view showing the chip modules after the extending step according to the present invention;

FIG. 5 is a schematic view showing that the chip modules are covered by covering material according to the present invention; and

FIG. 6 is a schematic view showing the wafer-level packaged structure according to the present invention.

FIG. 7 is a schematic view showing the second embodiment of the wafer-level packaged structure according to the present invention.

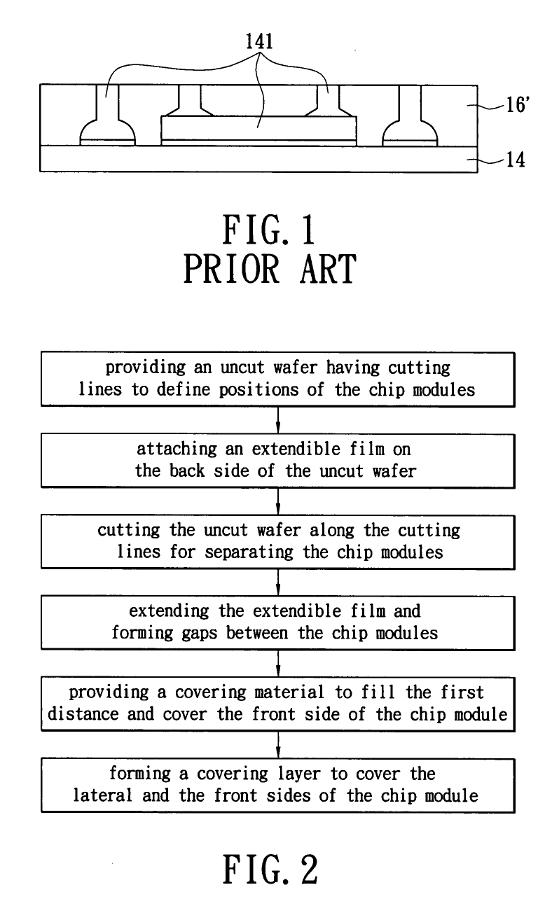

### DETAILED DESCRIPTION OF THE INVENTION

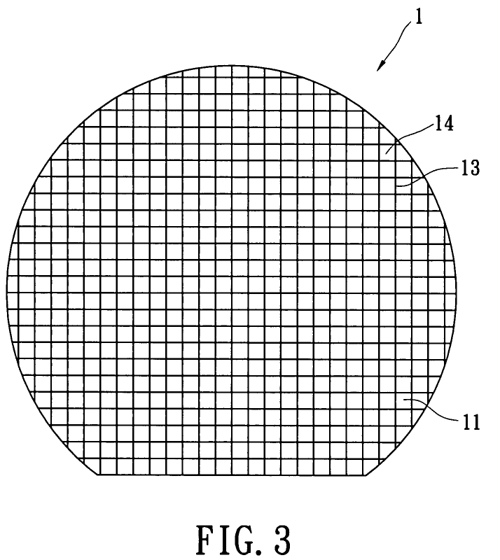

Please refer to FIG. 2, the invention discloses a wafer-level packaged structure. The wafer-level packaged structure is provided for preventing the lateral side of the chip module from damage by collision with the device. The manufacturing method includes following steps (please refer to FIGS. 3 to 6):

The first step (a) is to provide an uncut wafer 1, and in the preferred embodiment the uncut wafer 1 is a silicon wafer. The uncut wafer 1 has a front side 11 and a back side 12 connected to the front side 11. A plurality of cutting lines 13 are formed on the front side 11 or on the back side 12 of the uncut wafer 1 by semiconductor-manufacturing processes in order to define the positions of chip modules 14. In other words, the uncut wafer 1 is divided into chip modules 14 by the cutting lines 13. The chip module 14 is a wireless module such as an RF (ratio-frequency) module, but the module is not restricted to the foregoing modules.

In addition, a plurality of device portions 141 is formed by semiconductor-manufacturing processes on the front side 11 of the uncut wafer 1. Each of the device portions 141 is corresponding to each of the chip modules 14 and provides circuit and electronic functions. The semiconductor-manufacturing processes, such as lithograph processes, etching processes, and metal sputtering processes are familiar to those skilled in the art. Alternatively, the device portions 141 can be disposed on the front side 11 of the uncut wafer 1 by a surface mounting technology (SMT).

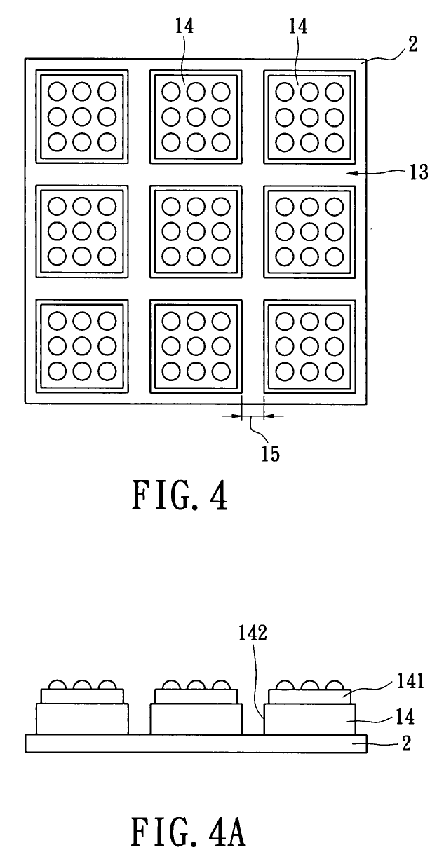

The second step (b) consists of attaching an extendible film 2 to the back side 12 of the uncut wafer 1 (please refer to FIGS. 4 and 4A). The extendible film 2 is made of polymers and is flexible. The extendible film 2 has an adhesive layer thereon so that the uncut wafer 1 can be attached to the adhesive layer of the extendible film 2. The extendible film 2 is a tape commonly used in semiconductor-manufacturing processes, such as a Die Attach Film (DAF). The tape is used to protect the uncut wafer 1 from breaking. When the uncut wafer 1 enters a cutting process, the wafer is usually mounted on the tape for holding the cut dies. Another type of tape is Blue Tape that is designed for the polishing, cutting or packaging. Blue Tape can protect the wafer or die from damage caused by the polishing or grinding process by absorbing the force and thus preventing the wafer from breaking. When the wafer is in the cutting process, the die is safely attached on the tape and the cutting quality is improved. Moreover, the tape makes it more convenient for the operator to hold the cut dies. Preferably, the extendible film 2 can have different adhesive strengths for different substrates, and the adhesive layer of the extendible film 2 will not be residual on the substrates after its removal. The extendibility of film 2 is necessary for the present invention. In other words, when a force is provided on the extendible film 2, the extendible film 2 can extend outwardly.

Step (c) is cutting the uncut wafer 1 along the cutting lines 13 for separating the chip modules 14. A cutter is used for cutting the uncut wafer 1 along the cutting lines 13 so as to form a plurality of individual chip modules 14. The cut chip modules 14 are firmly attached to the extendible film 2 due to the adhesive force of extendible film 2. The width of gaps 15 between the chip modules 14 formed after the cutting process is approximately the same as the width of the cutting tool.

Step (d) is to extend the extendible film 2 and to increase the width of gaps 15 between the chip modules 14. The extendible film 2 is stretched outwardly by applying a force to its edges and thus each of the chip modules 14 moves relative to the other chip modules 14 (please refer to FIGS. 4 and 4A). The width of gaps 15 between the chip modules 14 is increased to a predetermined value so as to expose the lateral side 142 of each chip module 14 (shown in FIG. 4A).

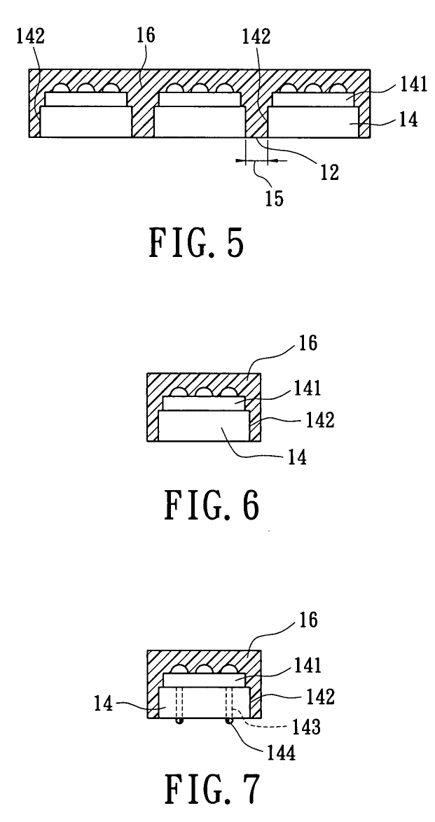

Step (e) is to fill the gaps 15 between the chip modules 14 with a covering material, thus creating a covering layer 16 on the front side 11 and the lateral side 142 of each chip module 14. Because the device portion 141 is mounted on the front side 11 of the chip module 14, the device portion 141 is also covered by the covering layer 16. The covering material is made from a polymer packaging material, such as thermosetting resin. Before curing, the thermosetting resins are usually liquid, powder, or malleable prior to curing, and designed to be molded into their final form. The curing process transforms the resin into a plastic or rubber by a cross-linking process. Because of the difference between the thermal-expansion coefficient of the thermosetting resin and that of the chip, internal stress is produced between the thermosetting resin and the chip, and breaking of the chip or separation or movement of the chip components may occur. Thus, some filler such as silicon dioxide powder, aluminum oxide powder, boron nitride powder or carbon fiber and another inorganic powder are added to the thermosetting resin. The filler has a low thermal-expansion coefficient and thus the stress is reduced. Note that above-described additives are familiar to those skilled in the art. In the present invention, the covering layer 16 is provided for covering the front side 11 and the lateral side 142 of each chip module 14 by a molding method. In other words, each chip module 14 is covered entirely by the covering layer 16 as shown in FIG. 5, where the extendible film 2 is not shown for clarity of the figure.

After step (e), a cutter is used for cutting along the cutting lines 13 for separating the chip modules 14 so that a plurality of chip modules 14 having covered front side 11 and lateral side 142 is produced (shown in FIG. 6). The width of the cutter is narrower than the width of gap 15 so that sufficient covering material will remain on the lateral side 142 of chip modules 14.

Accordingly, front side 11 and lateral side 142 of the chip modules 14 are both covered by the covering material. The wafer-level packaged structure comprises: a chip module 14 with a front side 11 and a lateral side 142. The device portion 141 is formed by semiconductor-manufacturing processes on the front side 11 of chip module 14. The covering layer 16 is provided for covering the front side 11 and the lateral side 142 of the chip module 14. The device portion 141 is formed by semiconductor-manufacturing processes, such as etching, lithograph processes or SMT methods on the front side 11 of chip module 14. The wafer-level packaged structure is formed by cutting an uncut wafer 1 by sawing or another cutting method. A plurality of connecting portions 144 is disposed on the back side 12 of chip module 14 and a plurality of through holes 143 penetrate through chip module 14 (shown in FIG. 7). Thus, the device portion 141 is connected with the connecting portions via the through holes 143 so that power or other controlling signals are transmitted to the device portion 141 via the connecting portions 144.

To sum up, the present invention achieves the following advantages:
1. The covering layer 16 protects the device portion 141 and also covers the lateral sides 142 of the chip modules 14. The lateral side 142 of chip modules 14 is not exposed and thus are prevented from being damaged when the operator moves the chip modules 14.
2. The extendible film 2 is employed in the present invention. The extendible film 2 is provided for moving the chip modules 14 relatively to each other. In other words, the manufacturing process is simplified as complex processes are no longer needed.

Although the present invention has been described with reference to the foregoing preferred embodiment, it is to be understood that the invention is not limited to the details thereof. Various equivalent variations and modifications may occur to those skilled in the art in view of the teachings of the present invention. Thus, all such variations and equivalent modifications are embraced within the scope of the invention as defined in the appended claims.

What is claimed is:

1. A wafer-level packaged structure, comprising:
a chip module having a front side and a lateral side;
a device portion disposed on the front side of the chip module; and
a covering layer covering the device portion and the lateral side of the chip module.

2. The wafer-level packaged structure according to claim 1, wherein the device portion is formed by semiconductor-manufacturing processes.

3. The wafer-level packaged structure according to claim 1, wherein the device portion is mounted on the front side by a surface mounting technology (SMT).

4. The wafer-level packaged structure according to claim 1, wherein the chip module is formed by cutting an uncut wafer.

5. The wafer-level packaged structure according to claim 1, wherein the chip module has a back side connected to the front side of the chip module.

6. The wafer-level packaged structure according to claim 5, further comprising a plurality of connecting portions, wherein the connecting portions are connected electrically with the device portion via holes penetrating the chip module.

7. A wafer-level packaging method, comprising:
(a) providing an uncut wafer having a plurality of chip modules thereon, wherein the uncut wafer has a front side and a back side connected to the front side, the front side has a plurality of cutting lines thereon for defining positions of the chip modules;
(b) attaching an extendible film on the back side of the uncut wafer;
(c) cutting the uncut wafer along the cutting lines for separating the chip modules;
(d) extending the extendible film and forming gaps between the chip modules; and
(e) forming a covering layer for covering front sides and lateral sides of the chip modules.

8. The wafer-level packaging method according to claim 7, further comprising a step of forming a plurality of device portions on the front side of the chip modules by semiconductor-manufacturing processes prior to step (a).

9. The wafer-level packaging method according to claim 7, further comprising the step of forming a plurality of device portions on the front side of the chip modules by a surface mounting technology (SMT) prior to step (a).

10. The wafer-level packaging method according to claim 7, wherein the extendible film is made of polymers.

11. The wafer-level packaging method according to claim 7, wherein after step (c) the chip modules remain firmly attached to the extendible film.

12. The wafer-level packaging method according to claim 7, wherein in step (d) a force is provided to extend the extendible film and to form the gaps with a predetermined width between the chip modules to expose lateral sides of the chip modules.

13. The wafer-level packaging method according to claim 12, wherein in step (e) the covering layer covers the front sides and the lateral sides of the chip modules by a molding method.

14. The wafer-level packaging method according to claim 7, further comprising a step of providing a cutter cutting along the cutting lines for separating the chip modules with covered lateral sides after step (e).

15. The wafer-level packaging method according to claim 14, wherein the width of the cutter is narrower than the width of the gap.
